(19) United States
(12) Patent Application Publication
(10) Pub. No.: US 2010/0096629 A1
(43) Pub. Date: Apr. 22, 2010

(54) MULTI-CHIP MODULE FOR AUTOMATIC FAILURE ANALYSIS

(75) Inventor: Yeow Chyi CHEN, Taipei County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/254,156

(22) Filed: Oct. 20, 2008

(51) Int. Cl. H01L 25/065

(52) U.S. Cl. 257/48; 257/E25.029

(57) ABSTRACT

The invention provides a multi-chip module. In one embodiment, the multi-chip module comprises a serial flash die and a primary die, and the primary die comprises a built-in self-test controller and a serial flash controller. The built-in self-test controller generates a write command to write first data to a memory location of the serial flash die, generates a read command to read second data from the memory location of the serial flash die, and compares the second data with the first data to determine whether the memory location is defective for generating failed address information about the serial flash die. The serial flash controller accesses the serial flash die according to the write command and the read command.

### BACKGROUND OF THE INVENTION

1. Field of the Invention

The invention relates to chip failure analysis of a multi-chip module (MCM), and more particularly to chip failure analysis of a multi-chip module comprising a serial flash die.

2. Description of the Related Art

A Multi-Chip Module (MCM) is a specialized electronic package where multiple integrated circuits (ICs) or semiconductor dies are packaged in such a way as to facilitate their use as a single IC. Because a multi-chip module comprises multiple component chips, failure of a multi-chip module may be caused by failure of any one of the component chips. To ascertain source of chip failure, failure analysis of multi-chip modules therefore must identify which component chip of a failed multi-chip module is defective.

For example, a serial flash memory is a common component chip of a multi-chip module. Failure analysis of a multi-chip module comprising a serial flash memory is therefore an essential duty for manufacturers of multi-chip modules. Referring to FIG. 1, a block diagram of a conventional multi-chip module 100 comprising a serial flash die 120 is shown. In addition to the serial flash die 120, the multi-chip module 100 also comprises a primary die 110, such as a microcontroller module or a digital signal processing module. A serial flash controller 112 accesses the serial flash die 120 through four bonding lines 141˜144.

The four bonding lines 141˜144 couples the primary die 110 to the serial flash die 120. The signal line 144 provides the serial flash die 120 with a chip select signal. The signal line 143 provides the serial flash die 120 with a clock signal generated by the serial flash controller 112. The signal lines 142 couples an output data pin PAD_DO of the primary die 110 to an input data pin SF_DI of the serial flash die 120 to provide a data transmission path from the primary die 110 to the serial flash die 120. The signal lines 141 couples an output data pin SF_DO of the serial flash die 120 to an input data pin PAD_DI of the primary die 110 to provide a data transmission path from the serial flash die 120 to the primary die 110.

Failure of a multi-chip module 100 may be caused by two factors. First, if the primary die 110 functions well, a defective serial flash die 120 may cause failure of the multi-chip module 100. Secondly, error of the bonding lines 141˜144 may also induce failure of the multi-chip module 100. Thus, a complete method for failure analysis of a multi-chip module 100 must not only determine whether the multi-chip module is defective but also determine whether a bonding error or defect of the serial flash die is the source of error. Thus, a multi-chip module designed for automatic failure analysis is required.

### BRIEF SUMMARY OF THE INVENTION

The invention provides a multi-chip module. In one embodiment, the multi-chip module comprises a serial flash die and a primary die, and the primary die comprises a built-in self-test controller and a serial flash controller. The built-in self-test controller generates a write command to write first data to a memory location of the serial flash die, generates a read command to read second data from the memory location of the serial flash die, and compares the second data with the first data to determine whether the memory location is defective for generating failed address information about the serial flash die. The serial flash controller accesses the serial flash die according to the write command and the read command.

The invention also provides a multi-chip module. In one embodiment, the multi-chip module is coupled to an external test machine and comprises a serial flash die and a primary die. The primary die forwards a plurality of first signals generated by the external test machine to the serial flash die when a bypass mode is enabled, and forwards at least one second signal generated in response to the first signals to the external test machine when the bypass mode is enabled, wherein the first signals and the second signal bypass all component circuits of the primary die to be directly transmitted between the external test machine and the serial flash die when the bypass mode is enabled.

The invention also provides a multi-chip module. In one embodiment, the multi-chip module comprises a serial flash die and a primary die. The primary die is coupled to the serial flash die through a plurality of bonding lines. The serial flash die comprises a logic unit generating an output signal according to a plurality of input signals. The primary die sends the input signals to the logic unit through the bonding lines, and determines whether the bonding lines fail according to correctness of the output signal.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a block diagram of a conventional multi-chip module comprising a serial flash die;

FIG. 2A is a block diagram of a multi-chip module for automatic failure analysis according to the invention;

FIG. 2B is a block diagram of another embodiment of a multi-chip module for automatic failure analysis according to the invention;

FIG. 3 is a block diagram of a multi-chip module switched to a bypass test mode according to the invention;

FIG. 4 is a block diagram of a multi-chip module capable of determining occurrence of bonding failure according to the invention; and

FIG. 5 shows an embodiment of bit values of the input signals serially generated by a boundary scan controller of FIG. 4.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

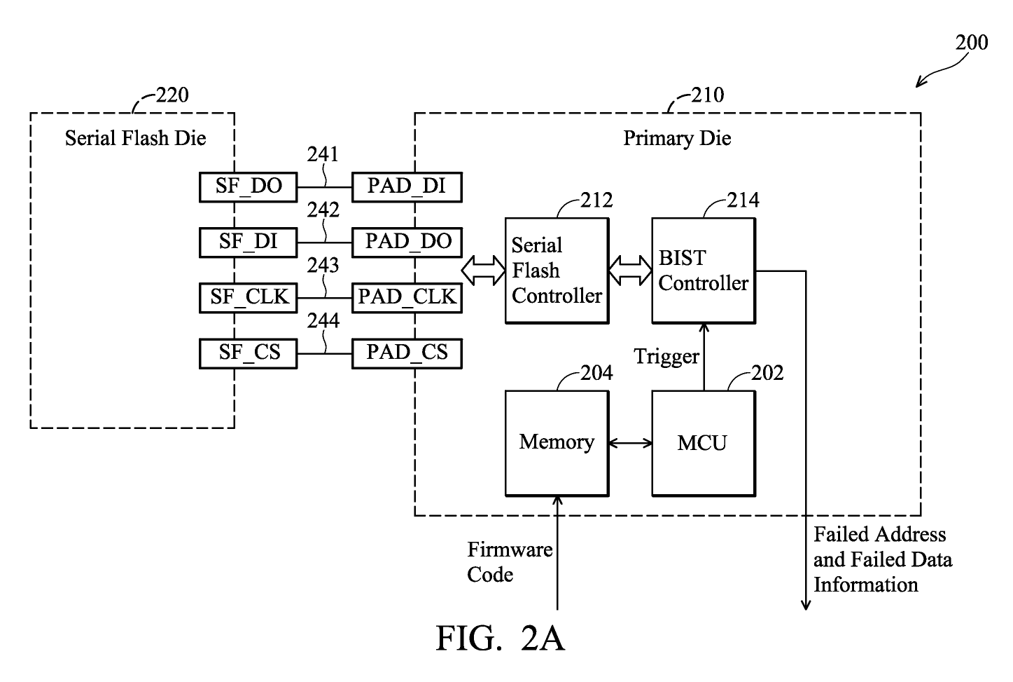

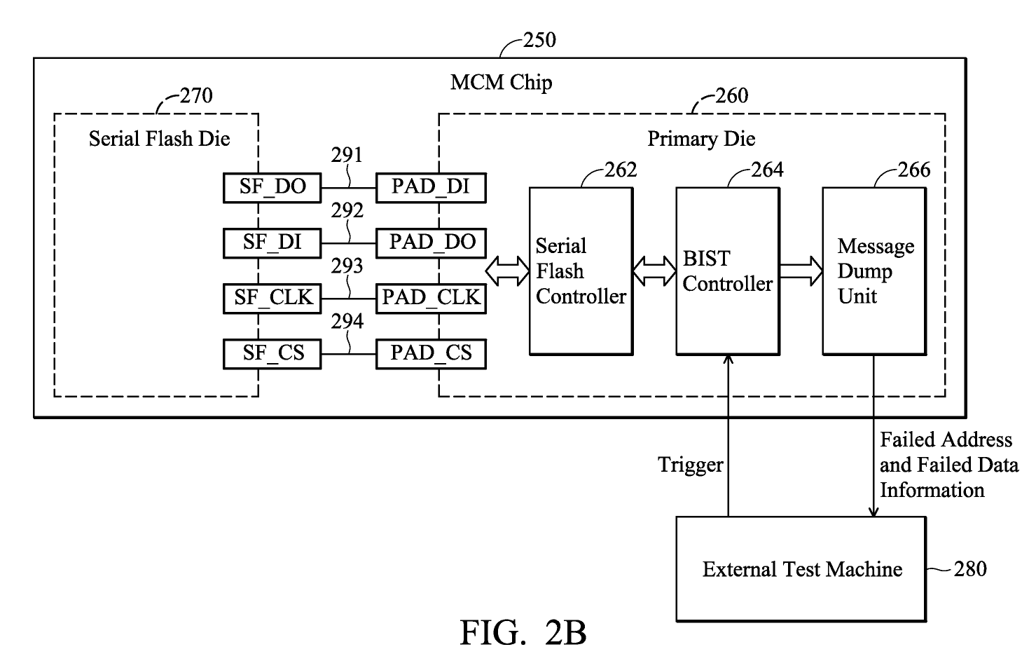

Referring to FIG. 2A, a block diagram of a multi-chip module 200 for automatic failure analysis according to the invention is shown. The multi-chip module 200 comprises a primary die 210 and a serial flash die 220. The serial flash die 220 is in effect a flash memory for data storage. The primary die 210 is coupled to the serial flash die 220 through multiple bonding lines 241˜244. When the primary die 210 requires accessing the serial flash die 220, the serial flash controller 212 practically accesses the serial flash die 220 according to instructions of the primary die 210.

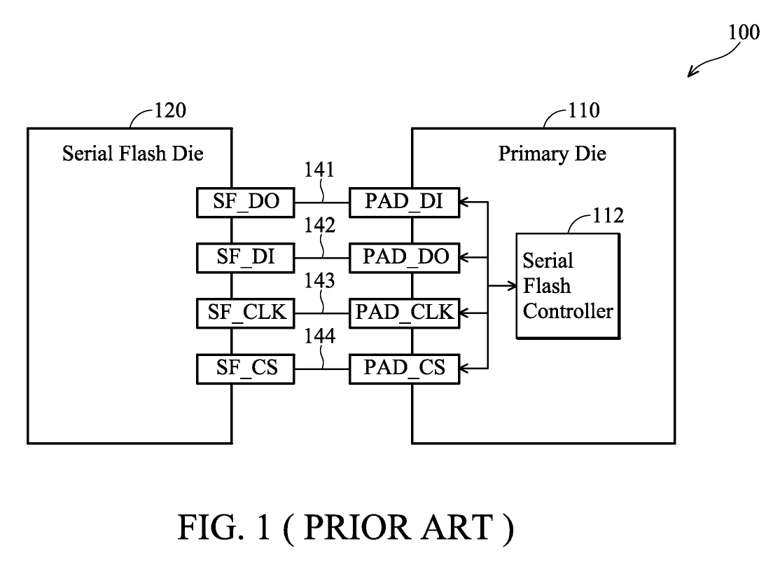

Although the multi-chip module 200 is roughly similar to the multi-chip module 100 of FIG. 1, the primary die 210 of the multi-chip module 200 comprises a built-in self-test (BIST) controller 214 automatically performing a failure analysis of the serial flash die 220. In addition to the serial flash controller 212 and the built-in self-test controller 214, the primary die 210 further comprises a microcontroller unit (MCU) 202 and a memory 204. A segment of firmware code is first loaded to the memory 204. In one embodiment, the firmware code is downloaded to the memory 204 through an IDE interface. The microcontroller unit 202 then executes the firmware code stored in the memory 204 to trigger operation of the built-in self-test controller 214. The built-in self-test controller 214 then starts to perform failure analysis of the serial flash die 220 to generate failed address information about the serial flash die 220.

For example, the built-in self-test controller 214 serially tests functionality of each memory location of the serial flash die 220. The built-in self-test controller 214 first generates a write command to write first data to a target memory location of the serial flash die 220. The serial flash controller 212 then accesses the serial flash die 220 according to the write command. The built-in self-test controller 214 then generates a read command to read second data from the target memory location of the serial flash die 220, and compares the second data with the first data to determine whether the target memory location of the serial flash die 220 is defective. When the second data is not identical to the first data, the built-in self-test controller 214 takes the target memory location as a defective memory location, and the built-in self-test controller 214 then generates the failed address information comprising address of the target memory location. After all memory locations of the serial flash die 220 are completely tested, the failed address information comprises addresses of all defective memory locations of the serial flash die 220, and a defective multi-chip module 200 is thus identified.

In addition to being triggered by an internal microcontroller unit, test operation of a built-in self-test controller can also be triggered by an external test machine. Referring to FIG. 2B, a block diagram of another embodiment of a multi-chip module 250 for automatic failure analysis according to the invention is shown. The multi-chip module 250 is similar to the multi-chip module 200 of FIG. 2A, except that the primary die 260 further comprises a message dump unit 266. An external test machine 280 is coupled to the multi-chip module 250 through a serial in-circuit emulator (S-ICE) interface (not shown). When the external test machine 280 sends a trigger signal to the built-in self test controller 264, the built-in self test controller 264 performs a failure analysis test on the serial flash die 270 as the built-in self test controller 214 to generate failed address information. The message dump unit 266 then converts the failed address information to a format acceptable for the external test machine 280. Thus, the external test machine 280 can determine whether the multi-chip module 250 is defective.

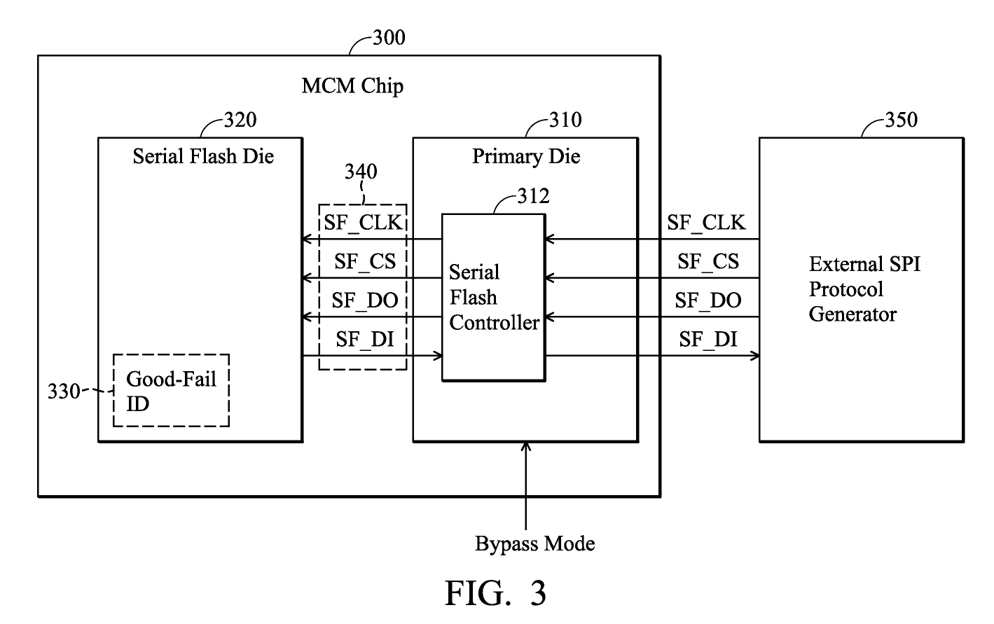

A failed multi-chip module can be identified according to the built-in self-test controllers 214 and 264 of FIGS. 2A and 2B. The failure of the multi-chip module, however, can be induced by bonding failure or a defective serial flash die. To determine which factor causes the failure of the multi-chip module, a method for directly testing a serial flash die of a multi-chip module is provided. Referring to FIG. 3, a block diagram of a multi-chip module 300 switched to a bypass test mode according to the invention is shown. Accordingly, the multi-chip die 300 also comprises a primary die 310 and a serial flash die 320. The primary die 310 comprises a serial flash controller 312 accesses the serial flash die 320 through multiple bonding lines 340 according to the primary die 310.

An external test machine 350 is coupled to the multi-chip module 300. In one embodiment, the external test machine 350 is a serial peripheral interface (SPI) protocol generator. In one embodiment, after a power-on configuration, the multi-chip module 300 can be switched to a bypass test mode according to a bypass mode signal. When the multi-chip module 300 is switched to the bypass test mode, multiple signals can bypass all component circuits, such as the serial flash controller 312, of the primary die 310 to be directly transmitted between the external test machine 350 and the serial flash die 320. Thus, the external test machine 350 can generate access signals to directly test memory locations of the serial flash die 320 of the multi-chip module 300, and determine whether the serial flash die 320 is defective according to data read out from the serial flash die 320.

The external test machine 350 first generates a set of first signals sent to the primary die 310. In one embodiment, the first signals comprises a clock signal SF_CLK, a chip select signal SF_CS, and a first data signal SF_DO carrying data sent to the serial flash die 320. When the bypass test mode is enabled, the primary die 310 directly forwards the first signals generated by the external test machine 350 to the serial flash die 320. The serial flash die 320 then generates at least one second signal in response to the first signals. In one embodiment, the second signal comprises a second data signal SF_DI carrying data output by the serial flash die 320. The primary die 310 then directly forwards the second signal to the external test machine 350. Thus, the first signals and the second signal bypass all component circuits of the primary die 310 to be transmitted between the external test machine 350 and the serial flash die 320 when the bypass mode is enabled. The external test machine 350 generates the first signals to test memory locations of the serial flash die 320, and determines whether the serial flash die 320 is defective according to the second signal.

If the external test machine 350 finds that read out data of the second signal is not correct, the test error may be induced by bonding failures between the primary die 310 and the serial flash die 320 or defects of the serial flash die 320. To determine which factor causes the test error, a flash chip vendor providing the serial flash die 320 is requested to store a good-fail identification 330 identifying whether the serial flash die 320 is defective according to a production-line test of the flash chip vendor in advance. After the external test machine 350 determines a test result indicating whether the serial flash die passes the failure analysis test, the external test machine 350 reads the good-fail identification from the serial flash die 320 and compares the good-fail identification with the test result to determine whether a bonding failure between the primary die 310 and the serial flash die 320 occurs. When the test result does not coincide with the good-fail identification, the external test machine 350 determines that bonding failure occurs. Thus, the test error is induced by bonding failure rather than defect of the serial flash die 320.

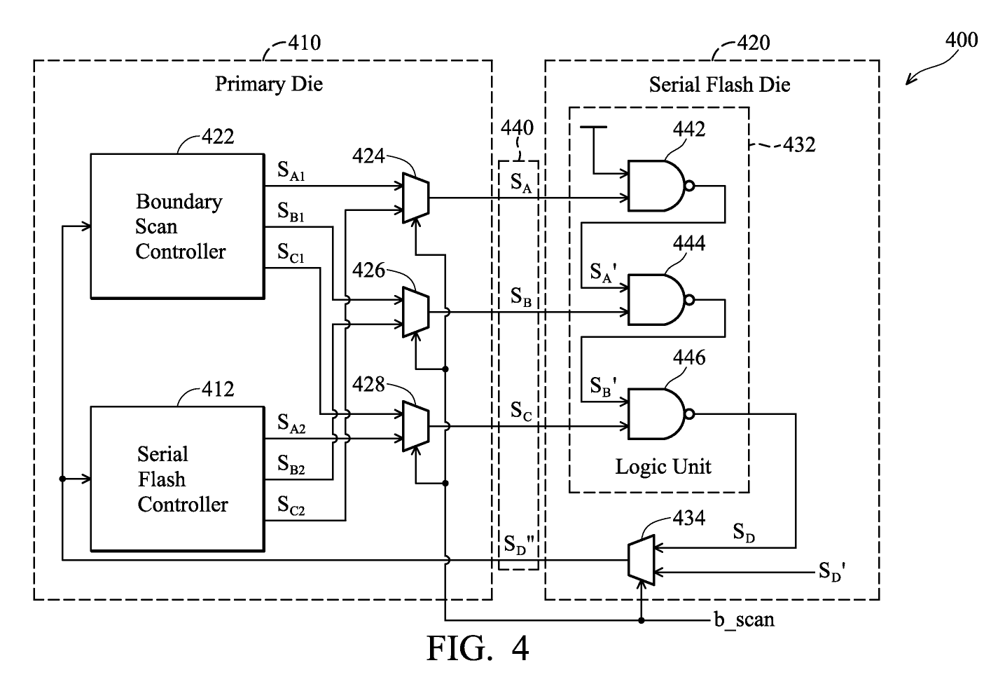

Although the multi-chip module 300 can infer occurrence of bonding failure, a method for directly determining whether bonding failure between a primary die and a serial flash die occurs is provided. Referring to FIG. 4, a block diagram of a multi-chip module 400 capable of determining occurrence of bonding failure according to the invention is shown. The multi-chip module 400 comprises a primary die 410 and a serial flash die 420. The serial flash die 420 is coupled to the primary die 410 through a plurality of bonding lines 440, wherein signals S_{A}, S_{B}, and S_{C} are transmitted from the primary die 410 to the serial flash die 420 through three of the bonding lines, and a signal S_{D}″ is transmitted from the serial flash die 420 to the primary die 410.

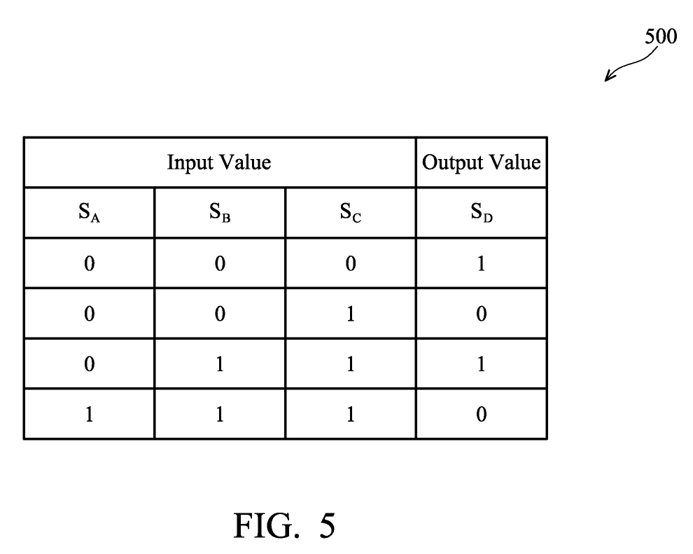

The multi-chip module 400 can directly determine whether bonding failure occurs in the bonding lines 440. The primary die 410 comprises a boundary scan controller 422, a serial flash controller 412, and multiplexers 424, 426, and 428, wherein the boundary scan controller 422 is related to verifying the connection situation between dies. When the multi-chip module 400 is switched to a boundary scan mode, a boundary scan signal b_scan is enabled, and the multiplexers 424, 426, and 428 respectively forward the signals S_{A1}, S_{B1}, and S_{C1} generated by the boundary scan controller 422 as the signals S_{A}, S_{B}, and S_{C} to the serial flash die 420. The boundary scan controller 422 generates a series of bits in different permutation as the input signals S_{A}, S_{B}, and S_{C}. Referring to FIG. 5, an embodiment of bit values of the input signals S_{A}, S_{B}, and S_{C} serially generated by the boundary scan controller 422 is shown. A first set of bit values of the input signals S_{A}, S_{B}, and S_{C} are (0, 0, 0), followed by a second set of bit values of (0, 0, 1), a third set of bit values of (0, 1, 1), and a fourth set of bit values of (1, 1, 1).

The serial flash die 420 comprises a logic unit 432 generating the output signal S_{D} according to the input signals S_{A}, S_{B}, and S_{C}. In one embodiment, the logic unit 432 is a NAND-gate tree. The logic unit 432 comprises three NAND gates 442, 444, and 446. The NAND gate 442 performs a NAND operation on a high level voltage and the input signal SA to generate a result signal S_{A}′. The NAND gate 444 then performs a NAND operation on the result signal S_{A}′ and the input signal S_{B} to generate a result signal S_{B}′. The NAND gate 446 then performs a NAND operation on the result signal S_{B}′ and the input signal S_{C} to generate an output signal S_{D}. Thus, bit values of the output signal S_{D} corresponding to the input bit values of signals S_{A}, S_{B}, and S_{C} shown in FIG. 5 are respectively 1, 0, 1, and 0.

When the boundary scan signal b_scan is enabled, a multiplexer 434 passes the output signal S_{D} as the signal S_{D}″ to the primary die 410. When the boundary scan controller 410 receives the output signal S_{D}″, it can determine whether the bonding lines fail according to correctness of the output signal S_{D}″. For example, if bonding fail occurs in one of the bonding lines 440, the bit values of the output signal S_{D}″ will not be the exact values of “1, 0, 1, and 0”, and the boundary scan controller 422 determines that bonding failure occurs. Thus, the multi-chip module 400 can directly determine whether bonding failure occurs in the bonding lines 440 according to the table of signals S_{A}, S_{B}, S_{C}, and S_{D} showed in FIG. 5.

The invention provides multiple embodiments of a multi-chip module for automatic failure analysis. The multi-chip module comprises a primary die and a serial flash die. In one embodiment, a built-in self-test controller of the primary die can automatically perform testing of the serial flash die to generate fail address information about the serial flash die. In another embodiment, the multi-chip module is switched to a bypass test mode, and an external test machine can directly access the serial flash die to determine whether the serial flash die has defects. In another embodiment, a boundary scan controller of the primary die can identify occurrence of bonding failure between the serial flash die and the primary die. Thus, errors of the multi-chip module are carefully identified to facilitate manufacturing and quality control of the multi-chip module.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A multi-chip module (MCM), comprising:
a serial flash die; and
a primary die, coupled to the serial flash die, comprising:
a built-in self-test (BIST) controller, generating a write command to write first data to a memory location of the serial flash die, generating a read command to read second data from the memory location of the serial flash die, and comparing the second data with the first data to determine whether the memory location is defective for generating failed address information about the serial flash die; and
a serial flash controller, coupled to the built-in self-test controller, accessing the serial flash die according to the write command and the read command.

2. The multi-chip module as claimed in claim 1, wherein the primary die further comprises:
a memory, storing a firmware code; and
a microcontroller unit, coupled to the built-in self-test controller, triggering operation of the built-in self-test controller according to the firmware code.

3. The multi-chip module as claimed in claim 1, wherein when the second data is not identical to the first data, the built-in self-test controller takes the memory location as a defect memory location and generates the failed address information comprising the address of the memory location.

4. The multi-chip module as claimed in claim 1, wherein operation of the built-in self-test controller is triggered by an external test machine through an external interface.

5. The multi-chip module as claimed in claim 4, wherein the primary die further comprises a message dump unit, coupled to the built-in self-test controller, converting the failed address information to a format understood by the external test machine.

6. A multi-chip module (MCM), coupled to an external test machine, comprising:
a serial flash die; and
a primary die, coupled to the serial flash die, forwarding a plurality of first signals generated by the external test machine to the serial flash die when a bypass mode is enabled, and forwarding at least one second signal generated in response to the first signal to the external test machine when the bypass mode is enabled,
wherein the first signals and the second signal bypass all component circuits of the primary die to be directly transmitted between the external test machine and the serial flash die when the bypass mode is enabled.

7. The multi-chip module as claimed in claim 6, wherein the external test machine generates the first signals to test memory locations of the serial flash die, and determines whether the serial flash die is defective according to the second signal.

8. The multi-chip module as claimed in claim 6, wherein the external test machine is a serial peripheral interface (SPI) protocol generator.

9. The multi-chip module as claimed in claim 6, wherein the component circuits comprise a serial flash controller accessing the serial flash die.

10. The multi-chip module as claimed in claim 6, wherein the first signals comprises a clock signal, a chip select signal, and a first data signal carrying data sent to the serial flash die, and the second signal comprises a second data signal carrying data output by the serial flash die.

11. The multi-chip module as claimed in claim 6, wherein the serial flash die comprises a good-fail identification identifying whether the serial flash die is defective according to a production-line test of a flash chip vendor.

12. The multi-chip module as claimed in claim 11, wherein the external test machine generates the first signals to test the serial flash die, determines a test result indicating whether the serial flash die passes the test according to the second signal, and compares the good-fail identification with the test result to determine whether a bonding failure between the primary die and the serial flash die occurs.

13. The multi-chip module as claimed in claim 12, wherein the external machine determines occurrence of the bonding failure when the good-fail identification does not coincide with the test result.

14. A multi-chip module (MCM), comprising:
a serial flash die, comprising a logic unit generating an output signal according to a plurality of input signals; and
a primary die, coupled to the serial flash die through a plurality of bonding lines, sending the input signals to the logic unit through the bonding lines, and determining whether the bonding lines fail according to correctness of the output signal.

15. The multi-chip module as claimed in claim 14, wherein the logic unit is a NAND-gate tree.

16. The multi-chip module as claimed in claim 15, wherein the input signals comprises a first input signal, a second input signal, and a third input signal, and the logic unit comprises:
a first NAND gate, performing a NAND operation on a high level voltage and the first input signal to generate a first result signal;
a second NAND gate, performing a NAND operation on the first result signal and the second input signal to generate a second result signal; and
a third NAND gate, performing a NAND operation on the second result signal and the third input signal to generate the output signal.

17. The multi-chip module as claimed in claim 14, wherein the input signals are a series of bits in different permutation.

18. The multi-chip module as claimed in claim 14, wherein the primary die comprises a boundary scan controller, generating the input signals and determining whether the bonding lines fail according to correctness of the output signal.
